(19) United States
(12) Patent Application Publication
(10) Pub. No.: US 2024/0170541 A1
(43) Pub. Date: May 23, 2024

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/511,608

(22) Filed: Nov. 16, 2023

(30) Foreign Application Priority Data
Nov. 18, 2022 (CN) 202211448910.7

(51) Int. Cl. H01L 29/20; H01L 29/06; H01L 29/423; H01L 29/66; H01L 29/775; H01L 29/786

(52) U.S. Cl. CPC H01L 29/2003; H01L 29/0673; H01L 29/42392; H01L 29/66469; H01L 29/775; H01L 29/78696

(57) ABSTRACT

Disclosed are a semiconductor structure and a manufacturing method thereof. The semiconductor structure includes: a substrate including a first region and a second region surrounding the first region; a patterned structure, a first N-type heavily-doped semiconductor layer, a channel layer, and a second N-type heavily-doped semiconductor layer arranged on the first region sequentially; a source electrode connected to the second N-type heavily-doped semiconductor layer; a drain electrode connected to the first N-type heavily-doped semiconductor layer; and a gate electrode wrapping around sidewall of the channel layer. The channel layer is a vertical channel structure wrapped by the gate electrode, which increases a gate control area, makes the electric field distribution more uniform, and greatly improves a control ability on the channel layer, so that a breakdown voltage is effectively increased, leakage current is reduced, dynamic characteristics are improved, and efficiency and linearity of the semiconductor structure are improved as well.

### CROSS-REFERENCE TO RELATED APPLICATIONS

The disclosure claims priority to Chinese Patent Application CN202211448910.7, filed on Nov. 18, 2022, the entire contents of which are incorporated herein by reference.

### TECHNICAL FIELD

The present disclosure relates to the technical field of semiconductor devices, and in particular, to a semiconductor structure and a manufacturing method thereof.

### BACKGROUND

Gallium Nitride (GaN) is a representative of the third-generation wide-bandgap semiconductor, and attracts widespread attention. GaN's superior performance is mainly reflected in: high electron mobility and high two-dimensional electron gas (2DEG) concentration. In addition, GaN material has stable chemical properties, high temperature resistance, and corrosion resistance, and have inherent advantages in high-frequency, high-power, and radiation-resistant applications.

In planar devices, current flows along a plane in quantum well formed by a heterojunction structure. When a device is under reverse bias, distribution of electric field is usually uneven, and generally a serious electric field concentration will be formed at an edge of a gate electrode or an edge of a drain electrode. Meanwhile, the electric field there will increase rapidly with increase of reverse voltage, and when a critical breakdown field strength is reached, the device is broken down.

A high breakdown voltage means that a working voltage range of devices is larger, a higher power density may be obtained, and reliability of the devices is higher. Therefore, how to improve the breakdown voltage of the devices is a key issue for researchers of electronic devices.

### SUMMARY

In order to solve the above technical problems, a semiconductor structure and a manufacturing method thereof are proposed.

A semiconductor structure provided by an embodiment of the present disclosure includes: a substrate including a first region and a second region, the second region surrounding the first region; a patterned structure, a first N-type heavily-doped semiconductor layer, a channel layer, and a second N-type heavily-doped semiconductor layer arranged on the first region sequentially; a source electrode connected to the second N-type heavily-doped semiconductor layer; a drain electrode connected to the first N-type heavily-doped semiconductor layer; and a gate electrode wrapping around sidewall of the channel layer.

Optionally, a nitrogen structure is disposed on a surface of the substrate arranged in the second region, and the surface of the substrate arranged in the second region is a nitrogen (N) surface.

Optionally, the semiconductor structure further includes a third N-type heavily-doped semiconductor layer arranged on the second region, surrounding and connecting to sidewall of the first N-type heavily-doped semiconductor layer, where the drain electrode is connected to the first N-type heavily-doped semiconductor layer through the third N-type heavily-doped semiconductor layer.

Optionally, material of the third N-type heavily-doped semiconductor layer is group III nitride material, and a surface of the third N-type heavily-doped semiconductor layer away from the substrate is a nitrogen surface.

Optionally, material of the patterned structure, the first N-type heavily-doped semiconductor layer, the channel layer, and the second N-type heavily-doped semiconductor layer is group III nitride material, and surfaces of the patterned structure, the first N-type heavily-doped semiconductor layer, the channel layer, and the second N-type heavily-doped semiconductor layer close to the substrate are nitrogen surfaces.

Optionally, the semiconductor structure further includes at least one N-type lightly-doped insertion layer arranged in the first N-type heavily-doped semiconductor layer and/or the third N-type heavily-doped semiconductor layer.

Optionally, the semiconductor structure further includes a dielectric layer wrapping around sidewall of the channel layer, where the gate electrode wraps around sidewall of the dielectric layer away from the channel layer.

Optionally, material of the dielectric layer comprises any one of high-dielectric-constant material of HfO₂, Al₂O₃ and Si₃N₄.

Optionally, the channel layer is an N-type lightly-doped layer, and a doping concentration of the channel layer is less than 1E18.

Optionally, the channel layer is a nanowire structure or a nanosheet structure.

Optionally, a shape of a cross-section of the patterned structure includes any one of triangle, circle, ellipse and polygon, and the cross-section is parallel to the substrate.

Another aspect of the present disclosure also provides a manufacturing method of a semiconductor structure, including:
providing a substrate, where the substrate comprises a first region and a second region and the second region surrounds the first region;
preparing a patterned structure on the first region;
preparing a third N-type heavily-doped semiconductor layer and a first N-type heavily-doped semiconductor layer on the substrate and the patterned structure simultaneously, where the third N-type heavily-doped semiconductor layer is arranged on the second region and the first N-type heavily-doped semiconductor layer is arranged on the patterned structure;
preparing a channel layer and a second N-type heavily-doped semiconductor layer on the first N-type heavily-doped semiconductor layer sequentially;
preparing a gate electrode wrapping around sidewall of the channel layer;
preparing a drain electrode on the third N-type heavily-doped semiconductor layer; and
preparing a source electrode on the second N-type heavily-doped semiconductor layer.

Optionally, after the preparing a patterned structure on the first region, the manufacturing method of a semiconductor structure further includes: nitriding a surface of the second region of the substrate.

Optionally, the preparing a channel layer and a second N-type heavily-doped semiconductor layer on the first N-type heavily-doped semiconductor layer sequentially includes:
preparing the channel layer and the second N-type heavily-doped semiconductor layer on the first N-type heavily-doped semiconductor layer and the third N-type heavily-doped semiconductor layer simultaneously and sequentially; and
removing a channel layer and a second N-type heavily-doped semiconductor layer on the third N-type heavily-doped semiconductor layer.

Optionally, the preparing a channel layer and a second N-type heavily-doped semiconductor layer on the first N-type heavily-doped semiconductor layer sequentially includes: preparing the channel layer and the second N-type heavily-doped semiconductor layer on the first N-type heavily-doped semiconductor layer and the third N-type heavily-doped semiconductor layer simultaneously and sequentially;
removing a third N-type heavily-doped semiconductor layer, a channel layer and a second N-type heavily-doped semiconductor layer arranged on the second region; and
preparing the drain electrode on sidewall of the first N-type heavily-doped semiconductor layer.

Optionally, material of the third N-type heavily-doped semiconductor layer, the patterned structure, the first N-type heavily-doped layer, the channel layer, and the second N-type heavily-doped semiconductor layer is group III nitride material, where
a surface of the third N-type heavily-doped semiconductor layer away from the substrate has a nitrogen surface, and surfaces of the patterned structure, the first N-type heavily-doped layer, the channel layer and the second N-type heavily-doped semiconductor layer close to the substrate are nitrogen surfaces.

Optionally, the preparing a gate electrode on sidewall of the channel layer further includes: preparing a dielectric layer on the third N-type heavily-doped semiconductor layer and the sidewall of the channel layer, wherein the dielectric layer wraps around the sidewall of the channel layer; and
preparing the gate electrode on the sidewall of the dielectric layer away from the channel layer, wherein the gate electrode wraps around the sidewall of the dielectric layer away from the channel layer.

Optionally, the preparing the third N-type heavily-doped semiconductor layer and the first N-type heavily-doped semiconductor layer on the substrate and the patterned structure simultaneously includes:
forming at least one N-type lightly-doped insertion layer in the third N-type heavily-doped semiconductor layer and/or the first N-type heavily-doped semiconductor layer

Optionally, a shape of a cross-section of the patterned structure comprises any one of triangle, circle, ellipse and polygon, and the cross-section is parallel to the substrate.

Optionally, the preparing a channel layer and a second N-type heavily-doped semiconductor layer on the first N-type heavily-doped layer sequentially includes:
performing an N-type ions doping process to the channel layer, wherein a doping concentration of the channel layer is less than 1E18.

According to the semiconductor structure and the manufacturing method thereof provided by the present disclosure, the channel layer is a vertical channel structure, and the gate electrode wraps around the sidewall of the channel layer which increases a gate control area, makes the electric field distribution more uniform, and greatly improves the ability of the gate electrode to control the channel layer, therefore the breakdown voltage is effectively increased, leakage current is reduced, dynamic characteristics are improved and efficiency and linearity of the semiconductor structure are improved as well.

The present disclosure realizes simultaneous preparation of the third N-type heavily-doped semiconductor layer and the first N-type heavily-doped semiconductor layer with different polar surfaces on the substrate. The first N-type heavily-doped semiconductor layer is arranged on the patterned structure. As the nitrogen surface of the group III nitride material is easier to etch, other film layers on the third N-type heavily-doped semiconductor layer are easier to remove than other film layers on the first N-type heavily-doped semiconductor layer, which ensures a good crystal quality of the channel layer arranged on the first N-type heavily-doped semiconductor layer and the second N-type heavily-doped semiconductor layer, greatly reduces preparation difficulty of the small-sized channel layer and the second N-type heavily-doped semiconductor layer and effectively reduces production cost.

According to the semiconductor structure and a manufacturing method thereof provided by the present disclosure, the shape of the cross-section of the channel layer above the patterned structure may be controlled by designing the shape of the cross-section of the patterned structure to meet different process requirements, Meanwhile, a narrower channel widths may be realized, witch greatly simplifies preparation difficulty of nanowire or nanosheet channel structure. The nanowire or nanosheet channel layer may effectively confines carriers, which greatly improves a transport rate of the carriers, effectively enhances the device performance. And the narrower channel width may further effectively increase the breakdown voltage, and greatly reduces the size of the semiconductor structure devices.

The drain electrode is provided on the nitrogen surface of the third N-type heavily-doped semiconductor layer, effectively utilizing the advantage of small ohmic contact resistance of material of the nitrogen surface and greatly improving device performance.

The at least one N-type lightly-doped insertion layer arranged in the first N-type heavily-doped semiconductor layer and/or the third N-type heavily-doped semiconductor layer effectively improves the breakdown voltage of the semiconductor structure in the off state.

### BRIEF DESCRIPTION OF THE DRAWINGS

Through a more detailed description of embodiments of the present disclosure with reference to the accompanying drawings, the above and other purposes, features and advantages of the present disclosure will become more obvious. The accompanying drawings are provided for further understanding of the present disclosure, and constitute a part of the specification. The accompanying drawings and the embodiments of the present disclosure are used to explain the present disclosure and do not constitute a limitation to the present disclosure. In the accompanying drawings, a same reference label is used for representing the same component or step. In the accompanying drawings, the same reference numerals generally represent the same components or steps.

FIG. 1 is a cross-sectional view of a semiconductor structure provided by an embodiment of the present disclosure.

FIG. 2 is a cross-sectional view of a semiconductor structure provided by another embodiment of the present disclosure.

FIGS. 3a to 3c are partial schematic diagrams of the semiconductor structure provided by an embodiment of the present disclosure.

FIGS. 4a to 4g are schematic diagrams of the steps of the manufacturing method of the semiconductor structure provided by an embodiment of the present disclosure.

FIG. 5 is a cross-sectional view of a semiconductor structure provided by another embodiment of the present disclosure.

FIG. 6 is a cross-sectional view of a semiconductor structure provided by another embodiment of the present disclosure.

### DETAILED DESCRIPTION OF THE EMBODIMENTS

The technical solutions in the embodiments of the present disclosure will be clearly and completely described below with reference to the accompanying drawings in the embodiments of the present disclosure. Apparently, the described embodiments are only a part of the embodiments of the present disclosure, but not all of the embodiments. Based on the embodiments in the present disclosure, all other embodiments obtained by those skilled in the art without creative efforts shall fall within the protection scope of the present disclosure.

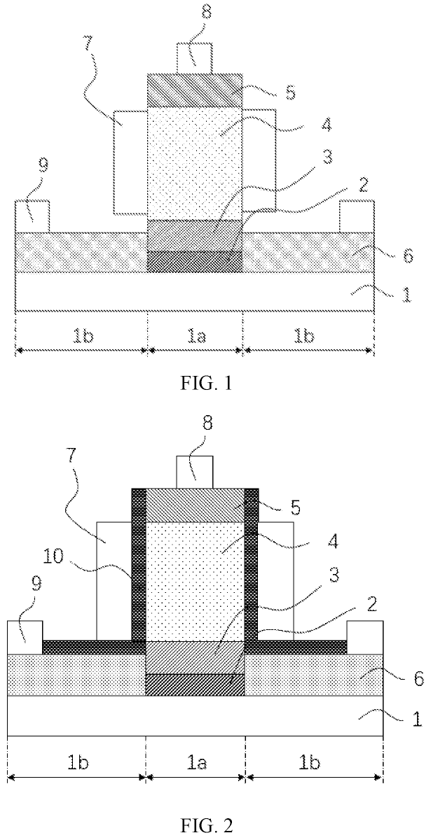

As shown in FIG. 1, FIG. 1 is a cross-sectional view of the semiconductor structure provided by an embodiment of the present disclosure. The semiconductor structure includes: a substrate 1 including a first region 1a and a second region 1b, the second region 1b surrounding the first region 1a; a patterned structure 2, a first N-type heavily-doped semiconductor layer 3, a channel layer 4 and a second N-type heavily-doped semiconductor layer 5 arranged on the first region 1a sequentially; a third N-type heavily-doped semiconductor layer 6 arranged on the second region 1b; a source electrode 8 connected to the second N-type heavily-doped semiconductor layer 5; a drain electrode 9 connected to third N-type heavily-doped semiconductor layer 6; and a gate electrode 7 wrapping around sidewall of the channel layer 4.

The channel layer 4 of the semiconductor structure provided by the embodiment shown in FIG. 1 is a vertical channel structure, and the gate electrode wraps around the sidewall of the channel layer 4 which greatly increases a gate control area, makes the electric field distribution more uniform, and greatly improves a control ability of the gate electrode to the channel layer, thereby effectively increasing a breakdown voltage, reducing leakage current, improving dynamic characteristics, and improving efficiency and linearity of the semiconductor structure.

As an optional embodiment, a nitrogen structure is disposed on the surface of the substrate 1 arranged in the second region 1b, a surface of the substrate arranged in the second region 1b is a nitrogen surface, and material of the substrate may be a conventional epitaxial substrate such as Si, SOI, sapphire, and SiC. The third N-type heavily-doped semiconductor layer 6 is arranged on the second region 1b. Material of the third N-type heavily-doped semiconductor layer 6 is group III nitride material, and the surface of a surface of the third N-type heavily-doped semiconductor layer 6 away from the substrate 1 is a nitrogen surface. Therein, a thickness of the third N-type heavily-doped semiconductor layer 6 is greater than a thickness of the patterned structure 2, the third N-type heavily-doped semiconductor layer 6 connects to sidewall of the first N-type heavily-doped semiconductor layer 3 by encircling, the drain electrode 9 is connected to the first N-type heavily-doped semiconductor layer 3 by the third N-type heavily-doped semiconductor layer 6, and the drain electrode 9 is formed on the third N-type heavily-doped semiconductor layer 6, which effectively utilizes the advantages of small ohmic contact resistance of nitrogen surface material, reduces the ohmic contact resistance between the drain electrode 9 and the third N-type heavily-doped semiconductor layer 3 and greatly improves device performance. In other embodiments, the drain electrode 9 is arranged on the third N-type heavily-doped semiconductor layer 3 in a ring shape so as to increase a contact area between the drain electrode 9 and the third N-type heavily-doped semiconductor layer 3 and further reduce the contact resistance. Optionally, material of the third N-type heavily-doped semiconductor layer 6 is GaN, and a doping concentration of N-type ions in the third N-type heavily-doped semiconductor layer 6 is greater than 1 E18.

In this embodiment, material of the patterned structure 2, the first N-type heavily-doped semiconductor layer 3, the channel layer 4 and the second N-type heavily-doped semiconductor layer 5 is group III nitride material. The surface of the patterned structure 2, the first N-type heavily-doped semiconductor layer 3, the channel layer 4 and the second N-type heavily-doped semiconductor layer 5 close to the substrate 1 is a nitrogen surface. Optionally, in this embodiment, material of patterned structure 2 is AlN, material of the first N-type heavily-doped semiconductor layer 3, the channel layer 4 and the second N-type heavily-doped semiconductor layer 5 is GaN. Therein, a doping concentration of N-type ions in the first N-type heavily-doped semiconductor layer 3 and the second N-type heavily-doped semiconductor layer 5 are greater than 1E18.

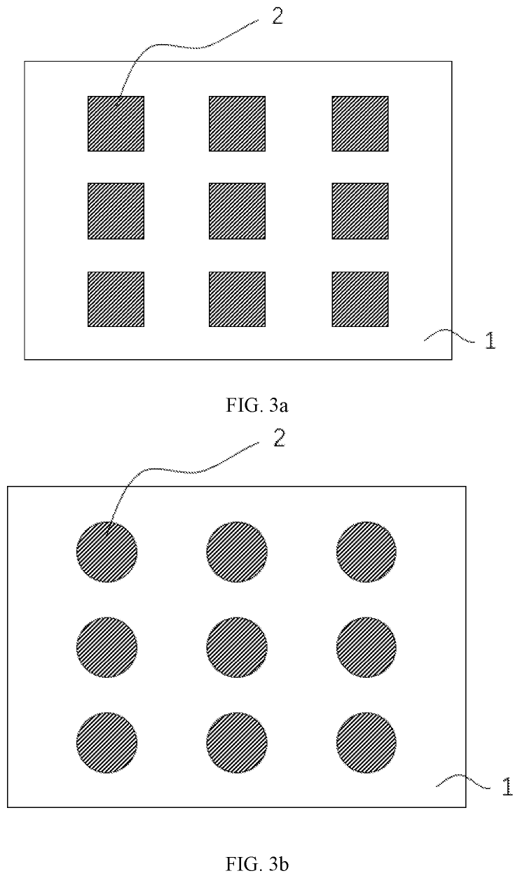

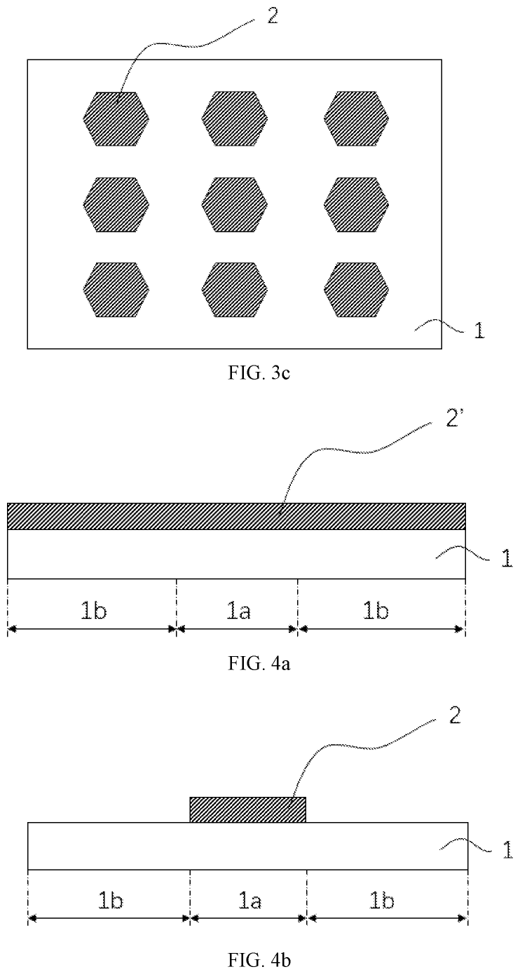

Optionally, the channel layer 4 may be an N-type lightly-doped layer, and a doping concentration of N-type ions in the channel layer 4 is less than 1E18. The N-type doped channel layer 4 greatly improves a transport rate of carriers. In this embodiment, the channel layer 4 may be a nanowire structure or a nanosheet structure, which realizes a narrower channel width, effectively confines the carriers, and further greatly improves the transport rate of the carriers, thereby improving device performance. Meanwhile, a narrower channel width is beneficial to enhance the control ability of the gate electrode 7 on the channel layer 4, thereby effectively increasing a breakdown voltage; and the nanowire or the nanosheet structure greatly reduces a size of the semiconductor structure device. Referring to FIG. 3a to 3c, the channel width of the channel layer 4 may be controlled by designing a cross-sectional shape of the patterned structure 2. The cross-sectional shape of the patterned structure 2 includes any one of triangle, circle, ellipse and polygon, and the cross-section is parallel to the substrate 1.

FIG. 2 is a cross-sectional view of a semiconductor structure provided by another embodiment of the present disclosure.

The content of the embodiment shown in FIG. 2 is roughly the same as that of the embodiment shown in FIG. 1, the only difference is that, as shown in FIG. 2, the semiconductor structure further includes a dielectric layer 10 wrapping around sidewall of the channel layer 4, where the gate electrode 7 wraps around sidewall of the dielectric layer 10 away from the channel layer 4. Optionally, material of the dielectric layer 10 includes any one of high-dielectric-constant material of HfO₂, Al₂O₃ and Si₃N₄. The ability of high dielectric constant dielectric material to bind charges is higher, therefore in the same external electric field, charges are not easy to be polarized and the polarized charges are less, resulting in that the polarized electric field is weaker and the short-channel effect of the semiconductor structure may be effectively avoided.

FIG. 5 is a cross-sectional view of a semiconductor structure provided by another embodiment of the present disclosure.

The content of the embodiment shown in FIG. 5 is substantially the same as that of the embodiment shown in FIG. 1 or the embodiment shown in FIG. 2, the only difference is that, as shown in FIG. 5, the semiconductor structure further includes at least one N-type lightly-doped insertion layer 30 arranged in the first N-type heavily-doped semiconductor layer 3 and/or the third N-type heavily-doped semiconductor layer 6. A doping concentration of N-type ion in the N-type lightly-doped insertion layer 30 is less than 1E18. The material of the N-type lightly-doped insertion layer 30 is group III nitride material, and optionally, the material of the N-type lightly-doped insertion layer 30 includes any one of AlN, AlGaN and GaN. The arrangement of the N-type lightly-doped insertion layer 30 effectively improves a breakdown voltage of the semiconductor structure in an off state.

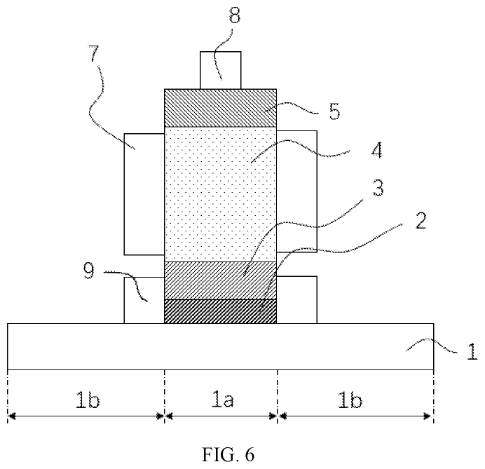

FIG. 6 is a cross-sectional view of a semiconductor structure provided by another embodiment of the present disclosure.

The content of the embodiment shown in FIG. 6 is substantially the same as that of any one of the embodiment shown in FIG. 1, the embodiment shown in FIG. 2, and the embodiment shown in FIG. 5, and the only difference is that, as shown in FIG. 6, the semiconductor structure provided by the embodiment shown in FIG. 6 includes: a substrate 1 including a first region 1a and a second region 1b, the second region 1b surrounding the first region 1a; a patterned structure 2, a first N-type heavily-doped semiconductor layer 3, a channel layer 4 and a second N-type heavily-doped semiconductor layer 5 arranged on the first region 1a sequentially; a source electrode 8 connected to the second N-type heavily-doped semiconductor layer 5; a drain electrode 9 connected to first N-type heavily-doped semiconductor layer 3; and a gate electrode 7 wrapping around sidewall of the channel layer 4. The drain electrode 9 is arranged on the second region 1b, and the drain electrode 9 may be a ring structure wrapping around the sidewall of the first N-type heavily-doped semiconductor layer 5.

The present embodiment also provides a manufacturing method of the above-mentioned semiconductor structure, including: providing a substrate 1, where the substrate 1 includes a first region 1a and a second region 1b and the second region 1b surrounds the first region 1a; preparing a patterned structure 2 on the first region 1a; preparing a third N-type heavily-doped semiconductor layer 6 and a first N-type heavily-doped semiconductor layer 3 on the substrate 1 and the patterned structure 2 simultaneously, where the third N-type heavily-doped semiconductor layer 6 is arranged on the second region 1b and the first N-type heavily-doped semiconductor layer 3 is arranged on the patterned structure 2; preparing a channel layer 4 and a second N-type heavily-doped semiconductor layer 5 on the first N-type heavily-doped semiconductor layer and the third N-type heavily-doped semiconductor layer 6 simultaneously, then removing the channel layer 4 arranged on the second region 1b, the second N-type heavily-doped semiconductor layer 5 and the third N-type heavily-doped semiconductor layer 6 arranged on the second region 1b; preparing a gate electrode 7 wrapping around sidewall of the channel layer 4; preparing a drain electrode 9 on sidewall of the first N-type heavily-doped semiconductor layer 3; and preparing a source electrode 8 on the second N-type heavily-doped semiconductor layer 5.

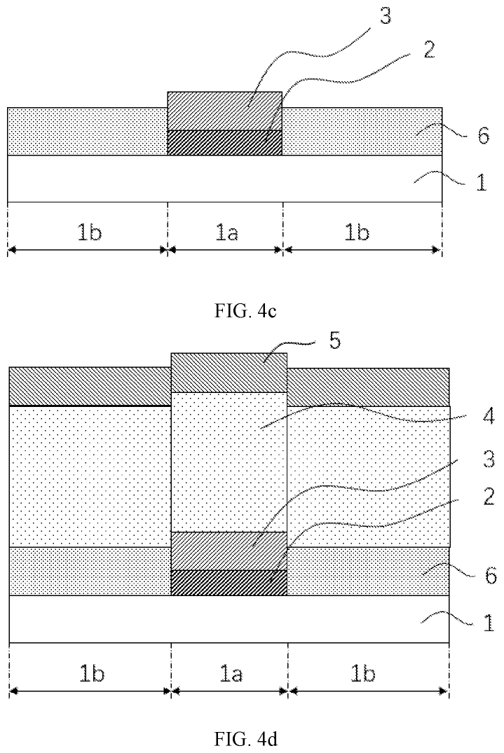

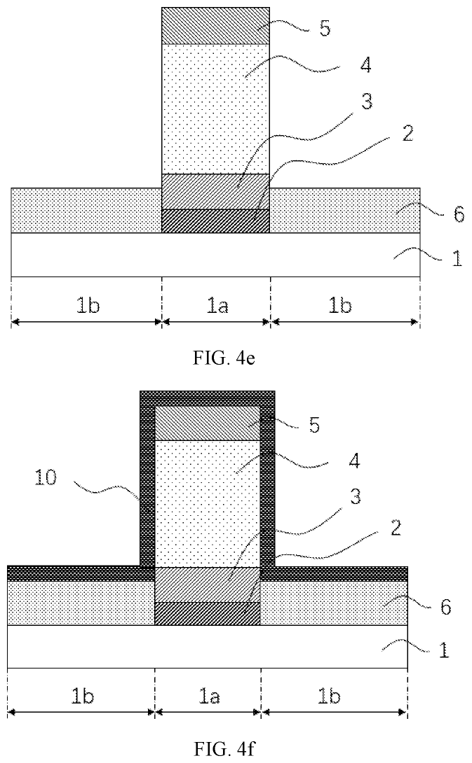

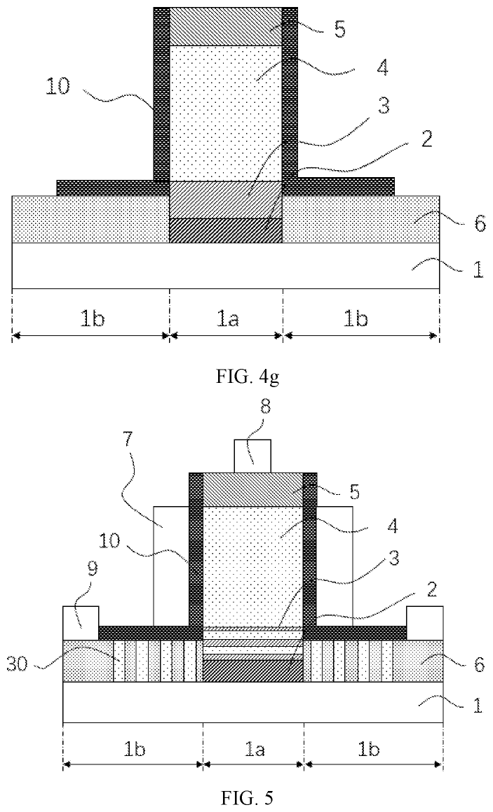

FIG. 4a to FIG. 4g are schematic diagrams of steps of a manufacturing. method of a semiconductor structure provided by an embodiment of the present disclosure

FIG. 4a to FIG. 4g provides the manufacturing method of the semiconductor structure provided by the above embodiment, as shown in FIG. 4a to FIG. 4g and FIG. 1, the manufacturing method includes: providing a substrate 1 including a first region 1a and a second region 1b, the second region 1b surrounding the first region 1a; preparing a patterned structure 2 on the first region 1a; preparing a third N-type heavily-doped semiconductor layer 6 and a first N-type heavily-doped semiconductor layer 3 on the substrate 1 and the patterned structure 2 simultaneously, where the third N-type heavily-doped semiconductor layer 6 is arranged on the second region 1b, the first N-type heavily-doped semiconductor layer 3 is arranged on patterned structure 2; preparing a channel layer 4 and a second N-type heavily-doped semiconductor layer 5 on the first N-type heavily-doped semiconductor layer 3 sequentially; preparing a gate electrode 7 wrapping around sidewall of channel layer 4; preparing a drain electrode 9 on the third N-type heavily-doped semiconductor layer 6; and preparing a source electrode 8 on the second N-type heavily-doped semiconductor layer 5.

Optionally, after the preparing a patterned structure 2 on the first region 1a, the manufacturing method further includes: nitriding a surface of the second region 1b of the substrate 1, so that a nitrogen structure is disposed on the surface of the substrate 1 arranged in the second region 1b and then the surface of the third N-type heavily-doped semiconductor layer 6 arranged on the second region 1b away from the substrate 1 is a nitrogen surface.

Specifically, the preparing a channel layer 4 and a second N-type heavily-doped semiconductor layer 5 on the first N-type heavily-doped semiconductor layer 3 includes: preparing the channel layer 4 and the second N-type heavily-doped semiconductor layer 5 on the first N-type heavily-doped semiconductor layer 3 and the third N-type heavily-doped semiconductor layer 6 simultaneously and sequentially; and removing the channel layer 4 arranged on third N-type heavily-doped semiconductor layer 6 and the second N-type heavily-doped semiconductor layer 5 arranged on third N-type heavily-doped semiconductor layer 6. Since the surface of the third N-type heavily-doped semiconductor layer 6 away from the substrate 1 has a nitrogen surface, the channel layer 4 arranged on the third N-type heavily-doped semiconductor layer 6 and the surface of the second N-type heavily-doped semiconductor layer 5 away from the substrate 1 has a nitrogen surface; and since the surface of one side of the patterned structure 2 close to the substrate 1 has a nitrogen surface, surfaces of the channel layer 4 on the patterned structure 2 and the second N-type heavily-doped semiconductor layer 5 close to the substrate 1 are nitrogen surfaces, that is, the polarity of the channel layer 4 and the second N-type heavily-doped semiconductor layer 5 on the first region 1a are opposite to the polarity of the channel layer 4 and the second N-type heavily-doped semiconductor layer 5 on second region 1b are opposite. The manufacturing methods of the first N-type heavily-doped semiconductor layer 3, the channel layer 4, the second N-type heavily-doped semiconductor layer 5 and the third N-type heavily-doped semiconductor layer 6 may be MOCVD. With characteristics that the nitrogen surface of group III nitride material is easier to etch, the channel layer 4 and the second N-type heavily-doped semiconductor layer 5 arranged on the third N-type heavily-doped semiconductor layer 6 are easier to remove to ensure a good crystal quality of the channel layer 4 and the second N-type heavily-doped semiconductor layer 5 on the first N-type heavily-doped semiconductor layer 3, which greatly reduces preparation difficulty of a small-size channel layer 4 and the second heavily-doped semiconductor layer 5, and makes it easy to reduce the size of the device and effectively reduces the production cost.

Therein, the preparing the patterned structure 2 on the first region 1a includes: preparing a nitride semiconductor layer 2′ on the entire surface of the substrate 1, and removing the nitride semiconductor layer 2′ on the second region 1b to form the patterned structure 2. Further referring to FIG. 3a to FIG. 3c, a cross-section shape of the patterned structure 2 includes any one of triangle, circle, ellipse, and polygon, and the cross-section is parallel to the substrate 1. The patterned structure 2 may be prepared by PVD deposition.

Optionally, the preparing the channel layer 4 and the second N-type heavily-doped semiconductor layer 5 on the first N-type heavily-doped layer 3 sequentially further includes: performing an N-type ions doping process to the channel layer 4 where a doping concentration of N-type ions of the channel layer 4 is less than 1E18. The doping method may be in-situ doping during the preparation of the channel layer 4 or N-type ion implantation after the preparation of the channel layer 4, which is not limited in this embodiment.

As an optional embodiment, the preparing a gate electrode 7 on sidewall of the channel layer 4 further includes: preparing a dielectric layer 10 on the third N-type heavily-doped semiconductor layer 6 and the sidewall of the channel layer 4 wrapping around the channel layer 4; preparing the gate electrode 7 on sidewall of dielectric layer 10 away from the channel layer 4 wrapping around the sidewall of dielectric layer 10 away from the channel layer 4. Specifically, the dielectric layer 10 may be prepared simultaneously on the surfaces of the third N-type heavily-doped semiconductor layer 6, the sidewall of the channel layer 4, the sidewall of the second N-type heavily-doped semiconductor layer 5, and the second N-type heavily-doped semiconductor layer. Optionally, the manufacturing method of the dielectric layer 10 is deposition; then the dielectric layer 10 on the second N-type heavily-doped semiconductor layer 5 is removed to expose the upper surface of the second N-type heavily-doped semiconductor layer 5; and part of the dielectric layer 10 arranged on the third N-type heavily-doped semiconductor layer 6 is removed to expose part of the surface of the third N-type heavily-doped semiconductor layer 6.

Further referring to FIG. 5, optionally, the preparing the third N-type heavily-doped semiconductor layer 6 and the first N-type heavily-doped semiconductor layer 3 on the substrate 1 and the patterned structure 2 simultaneously further includes: forming at least one N-type lightly-doped insertion layer 30 on the third N-type heavily-doped semiconductor layer 6 and/or first N-type heavily-doped semiconductor layer 3. The arrangement of the N-type lightly-doped insertion layer 30 effectively increase a breakdown voltage of the semiconductor structure in an off state.

The basic principles of the present disclosure have been described above in combination with specific embodiments, but it should be pointed out that the advantages, benefits, effects, mentioned in the disclosure are only examples rather than limitations, and these advantages, benefits, effects can't be understood as various embodiments of this disclosure must have. In addition, the specific details disclosed above are only for the purpose of illustration and understanding, rather than limitation, and the above details do not limit the disclosure to be implemented by using the above specific details.

What is claimed is:

1. A semiconductor structure, comprising:
a substrate comprising a first region and a second region, the second region surrounding the first region;
a patterned structure, a first N-type heavily-doped semiconductor layer, a channel layer, and a second N-type heavily-doped semiconductor layer arranged on the first region sequentially;
a source electrode connected to the second N-type heavily-doped semiconductor layer;
a drain electrode connected to the first N-type heavily-doped semiconductor layer; and
a gate electrode wrapping around sidewall of the channel layer.

2. The semiconductor structure of claim 1, wherein a nitrogen structure is disposed on a surface of the substrate arranged in the second region, and the surface of the substrate arranged in the second region is a nitrogen surface.

3. The semiconductor structure of claim 1, further comprising a third N-type heavily-doped semiconductor layer arranged on the second region, surrounding and connecting to sidewall of the first N-type heavily-doped semiconductor layer, wherein
the drain electrode is connected to the first N-type heavily-doped semiconductor layer through the third N-type heavily-doped semiconductor layer.

4. The semiconductor structure of claim 3, wherein a material of the third N-type heavily-doped semiconductor layer is a group III nitride material, and a surface of the third N-type heavily-doped semiconductor layer away from the substrate is a nitrogen surface.

5. The semiconductor structure of claim 1, wherein a material of the patterned structure, the first N-type heavily-doped semiconductor layer, the channel layer, and the second N-type heavily-doped semiconductor layer is a group III nitride material, and surfaces of the patterned structure, the first N-type heavily-doped semiconductor layer, the channel layer, and the second N-type heavily-doped semiconductor layer close to the substrate are nitrogen surfaces.

6. The semiconductor structure of claim 3, further comprising at least one N-type lightly-doped insertion layer arranged in the first N-type heavily-doped semiconductor layer and/or the third N-type heavily-doped semiconductor layer.

7. The semiconductor structure of claim 1, further comprising a dielectric layer wrapping around the sidewall of the channel layer, wherein the gate electrode wraps around sidewall of the dielectric layer away from the channel layer.

8. The semiconductor structure of claim 7, wherein a material of the dielectric layer comprises any one of high-dielectric-constant material of HfO₂, Al₂O₃ and Si₃N₄.

9. The semiconductor structure of claim 1, wherein the channel layer is an N-type lightly-doped layer, and a doping concentration of the channel layer is less than 1E18.

10. The semiconductor structure of claim 1, wherein the channel layer is a nanowire structure or a nanosheet structure.

11. The semiconductor structure of claim 1, wherein a shape of a cross-section of the patterned structure comprises any one of triangle, circle, ellipse and polygon, and the cross-section is parallel to the substrate.

12. A manufacturing method of a semiconductor structure, comprising:
providing a substrate, wherein the substrate comprises a first region and a second region, and the second region surrounds the first region;
preparing a patterned structure on the first region;
preparing a third N-type heavily-doped semiconductor layer and a first N-type heavily-doped semiconductor layer on the substrate and the patterned structure simultaneously, wherein the third N-type heavily-doped semiconductor layer is arranged on the second region, and the first N-type heavily-doped semiconductor layer is arranged on the patterned structure;
preparing a channel layer and a second N-type heavily-doped semiconductor layer on the first N-type heavily-doped semiconductor layer sequentially;
preparing a gate electrode wrapping around sidewall of the channel layer;
preparing a drain electrode on the third N-type heavily-doped semiconductor layer; and
preparing a source electrode on the second N-type heavily-doped semiconductor layer.

13. The manufacturing method of the semiconductor structure of claim 12, after the preparing a patterned structure on the first region, further comprising:
nitriding a surface of the second region of the substrate.

14. The manufacturing method of the semiconductor structure of claim 12, wherein the preparing a channel layer and a second N-type heavily-doped semiconductor layer on the first N-type heavily-doped semiconductor layer sequentially comprises:
preparing the channel layer and the second N-type heavily-doped semiconductor layer on the first N-type heavily-doped semiconductor layer and the third N-type heavily-doped semiconductor layer simultaneously and sequentially; and
removing a channel layer and a second N-type heavily-doped semiconductor layer on the third N-type heavily-doped semiconductor layer.

15. The manufacturing method of the semiconductor structure of claim 12, wherein the preparing a channel layer and a second N-type heavily-doped semiconductor layer on the first N-type heavily-doped semiconductor layer sequentially comprises:
preparing the channel layer and the second N-type heavily-doped semiconductor layer on the first N-type heavily-doped semiconductor layer and the third N-type heavily-doped semiconductor layer simultaneously and sequentially;
removing a third N-type heavily-doped semiconductor layer the channel layer and a second N-type heavily-doped semiconductor layer arranged on the second region; and
preparing the drain electrode on sidewall of the first N-type heavily-doped semiconductor layer.

16. The manufacturing method of the semiconductor structure of claim 12, wherein
a material of the third N-type heavily-doped semiconductor layer, the patterned structure, the first N-type heavily-doped layer, the channel layer, and the second N-type heavily-doped semiconductor layer is a group III nitride material, and
a surface of the third N-type heavily-doped semiconductor layer away from the substrate is a nitrogen surface, and surfaces of the patterned structure, the first N-type heavily-doped layer, the channel layer and the second N-type heavily-doped semiconductor layer close to the substrate are nitrogen surfaces.

17. The manufacturing method of the semiconductor structure of claim 12, wherein the preparing a gate electrode on sidewall of the channel layer further comprises:
preparing a dielectric layer on the third N-type heavily-doped semiconductor layer and the sidewall of the channel layer, wherein the dielectric layer wraps around the sidewall of the channel layer; and
preparing the gate electrode on the sidewall of the dielectric layer away from the channel layer, wherein the gate electrode wraps around the sidewall of the dielectric layer away from the channel layer.

18. The manufacturing method of the semiconductor structure of claim 16, wherein the preparing the third N-type heavily-doped semiconductor layer and the first N-type heavily-doped semiconductor layer on the substrate and the patterned structure simultaneously comprises:
forming at least one N-type lightly-doped insertion layer in the third N-type heavily-doped semiconductor layer and/or the first N-type heavily-doped semiconductor layer.

19. The manufacturing method of the semiconductor structure of claim 12, wherein
a shape of a cross-section of the patterned structure comprises any one of triangle, circle, ellipse, and polygon, and the cross-section is parallel to the substrate.

20. The manufacturing method of the semiconductor structure of claim 12, wherein the preparing a channel layer and a second N-type heavily-doped semiconductor layer on the first N-type heavily-doped layer sequentially comprises:
performing an N-type ions doping process to the channel layer, wherein a doping concentration of the channel layer is less than 1E18.
